(19) United States
(12) Patent Application Publication
(10) Pub. No.: US 2016/0049347 A1
(43) Pub. Date: Feb. 18, 2016

(54) SEMICONDUCTOR DEVICE

(71) Applicant: Panasonic Intellectual Property Management Co., Ltd., Osaka (JP)

(72) Inventors: NOBORU NEGORO, Osaka (JP); NAOHIRO TSURUMI, Kyoto (JP); DAISUKE SHIBATA, Kyoto (JP)

(21) Appl. No.: 14/925,608

(22) Filed: Oct. 28, 2015

Related U.S. Application Data
(63) Continuation of application No. PCT/JP2014/002443, filed on May 8, 2014.

(30) Foreign Application Priority Data
May 13, 2013 (JP) 2013-100942

(51) Int. Cl. H01L 23/31; H01L 29/872; H01L 29/47; H01L 23/29; H01L 29/51; H01L 21/02; H01L 29/205; H01L 21/283; H01L 21/56; H01L 29/06; H01L 29/20; H01L 29/778; H01L 29/66

(52) U.S. Cl. CPC H01L 23/3171; H01L 29/7787; H01L 29/872; H01L 29/475; H01L 23/291; H01L 29/518; H01L 29/513; H01L 29/66462; H01L 29/66212; H01L 29/205; H01L 21/283; H01L 21/563; H01L 29/0638; H01L 29/2003; H01L 21/02266; H01L 21/0217; H01L 21/02145; H01L 21/0214

(57) ABSTRACT

A semiconductor device includes a semiconductor layer made of nitride semiconductor, an ohmic electrode and a schottky electrode both formed on the semiconductor layer, a first insulating film containing a small amount of hydrogen per unit volume for covering the semiconductor device on a top face defined between the ohmic electrode and the schottky electrode and also covering the schottky electrode, and a second insulating film formed on the first insulating film and containing a greater amount of hydrogen per unit volume than the first insulating film.

### TECHNICAL FIELD

The present disclosure relates to a semiconductor device and a method for manufacturing the same.

### BACKGROUND ART

Nitride semiconductors, of which typical example is GaN, are wide-gap semiconductors. For instance, GaN and AIN have wide-gaps at a room temperature as large as 3.4 eV and 6.2 eV respectively. The nitride semiconductors have features of greater dielectric breakdown electric field, and greater saturated drift speed of electrons than those of compound semiconductors such as GaAs or Si semiconductors. A hetero-structure of AlGaN/GaN allows producing electric charges on hetero-interface due to spontaneous polarization and piezo polarization on (0001) plane, and also allows obtaining a sheet carrier concentration of at least 1×10¹³ cm⁻² even during an undoping process, so that diodes or HFETs (Hetero-junction Field Effect Transistor) having a greater current concentration are obtainable by using 2DEG (two dimensional electron gas) on the hetero-interface. For this reason, research and development of power devices that employ nitride semiconductors are progressing actively because the nitride semiconductors have advantages of greater output and higher withstand voltage.

The foregoing AlGaN refers to a ternary alloy such as AlₓGa₁₋ₓN (where x is some value satisfying the relation of 0≦x≦1). Hereinafter, a multi-element semiconductor alloy is abridged to its chemical symbols sequentially arranged, for instance, AlInN, GaInN and the like. The nitride semiconductor AlₓGa_{1-x-y}In_{y}N (where x, y are some values satisfying the relations of 0≦x≦1, 0≦y≦1, and 0≦(x+y)≦1) is abbreviated to AlGaInN.

Major devices of GaN power devices employ transistors or diodes using schottky electrodes. In general, a schottky transistor or diode is excellent in gate control and achieves a higher mutual conductance because of its structure, namely, an electrode is formed directly on a semiconductor layer; however, it has a drawback of a greater leakage current in reverse direction. To overcome this drawback, methods disclosed in Patent Literatures 1 and 2 have been proposed.

A schottky transistor employing AlGaN/GaN hetero-structure disclosed in Patent Literature 1 is described hereinafter with reference to FIG. 12. As shown in FIG. 12 that is a schematic cross sectional view, the schottky transistor forms semiconductor layered structure 1, in which substrate 6, buffer layer 7, GaN electron transit layer 8, AlGaN electron donor layer (barrier layer) 9, GaN surface layer (cap layer) 10 are layered in this order. Further, gate electrode 2 is formed on GaN surface layer, and ohmic electrode 3 is formed on AlGaN electron donor layer 9. On top of that, stoichiometry silicon nitride film 4 and non-stoichiometry silicon nitride film 5 are formed to cover exposed sections from the surface of semiconductor layered structure 1. Stoichiometry silicon nitride film 4 is an insulating film excellent in insulation, and contains a small amount of hydrogen, and yet, it has an N/Si ratio of 4/3 in stoichiometric composition. On the other hands, non-stoichiometry silicon nitride film 5 contains a large amount of hydrogen, and yet, it has a different stoichiometric composition ratio from that of stoichiometry silicon nitride film 4. Since stoichiometry silicon nitride film 4 is excellent in insulation, it aids in reducing the leakage current flowing in SiN film or in the interface between the semiconductor and the insulating film, and non-stoichiometry silicon nitride film 5 aids in stabilizing a not-yet terminated bond on the semiconductor surface because the hydrogen during the film deposition of nitride film 5 or the hydrogen in the insulating film passes through nitride film 4.

However, the structures disclosed in Patent Literatures 1 and 2 are not covered with protective films at their gate electrodes, thereby inviting an increase in the leakage current during film depositions such as the final passivation.

### CITED REFERENCES

### Patent Literature

PTL 1: Unexamined Japanese Patent Publication No. 2009-164300

PTL 2: Unexamined Japanese Patent Publication No. 2005-286135

### SUMMARY OF INVENTION

A device employing a schottky electrode encounters an increase in leakage current after deposition of an insulating film, so that it is estimated that hydrogen in depositing the film causes this increase. A leakage current in reverse direction of a diode that has been annealed (at approx. 250° C. that is equal to the temperature during the film deposition) is evaluated both in nitride atmosphere and hydrogen atmosphere. FIG. 13A shows the evaluation result, which clearly shows that the nitride atmosphere reduces the leakage current comparing with that before the annealing treatment while the hydrogen atmosphere increases the leakage current by as much as approx. 100 times. An increase in the leakage current is also observed after depositing SiN film of 100 nm thickness by P-CVD (plasma chemical vapor deposition) method, but this increase is not so great as observed in the hydrogen atmosphere.

FIG. 13B shows data of schottky barrier heights calculated before and after the annealing treatment. The data are used for investigating causes of the increase in the leakage current. In FIG. 13A, for instance, 1.E-07 is marked along the vertical axis, where E represents a power of ten, namely, 1.E-07 refers to 1×10⁻⁷. FIG. 13A shows a semi-logarithmic graph. Although initial schottky barrier heights have some dispersion, the barrier heights increase after the annealing treatment in the nitride atmosphere and the leakage current decreases. On the other hand, the barrier heights increase after the annealing treatment in the hydrogen atmosphere or after depositing SiN film by the P-CVD method, and the leakage current increases. These facts allow the inventors to assume that hydrogen causes some reaction on the interface between the metal and the semiconductor, thereby lowering the barrier heights, and the leakage current thus increases.

The present disclosure addresses the foregoing problem and aims to provide a semiconductor device that achieves reducing a gate leakage current or a leakage current in reverse direction in nitride semiconductor transistors or diodes.

To overcome the foregoing problem, the semiconductor device of the present disclosure comprises the following structural elements:
a semiconductor layer;
an ohmic electrode formed on the semiconductor layer;
a schottky electrode formed on the semiconductor layer;
a first insulating film covering the semiconductor layer at a top face defined between the ohmic electrode and the schottky electrode, and also covering the schottky electrode that forms a schottky junction with the semiconductor layer; and
a second insulating film formed on the first insulating film and containing a greater amount of hydrogen per unit volume than the first insulating film.

The structure discussed above allows covering the schottky electrode with the insulating film containing a less amount of hydrogen per unit volume, thereby preventing the hydrogen from entering an interface between the metal and the semiconductor. As a result, the leakage current is prevented from increasing.

The semiconductor device of the present disclosure prevents the leakage current from increasing after a passivation film is deposited.

### BRIEF DESCRIPTION OF DRAWINGS

FIG. 1 is a sectional view showing schematically a semiconductor device in accordance with a first embodiment.

FIG. 2 is a sectional view showing schematically a semiconductor device of a first modification of the first embodiment.

FIG. 3 is a sectional view showing schematically a semiconductor device of a second modification of the first embodiment.

FIG. 4 is a sectional view showing schematically a semiconductor device of a third modification of the first embodiment.

FIG. 5 is a sectional view showing schematically a semiconductor device in accordance with a second embodiment.

FIG. 6 is a sectional view showing schematically a semiconductor device of a modification of the second embodiment.

FIG. 7A is a sectional view around a gate electrode of an evaluation sample of a modified semiconductor device in accordance with the second embodiment.

FIG. 7B is a graph showing leakage properties of the modified semiconductor device in accordance with the second embodiment.

FIG. 8 is a sectional view showing schematically a semiconductor device in accordance with a third embodiment.

FIG. 9 is a graph showing leakage properties of the semiconductor device in accordance with the third embodiment.

FIG. 10A is a sectional view of the semiconductor device in accordance with the third embodiment, where the device has no recess structure on the anode side.

FIG. 10B is a graph showing leakage properties of the semiconductor device in accordance with the third embodiment, where the device has no recess structure on the anode side.

FIG. 11 is a sectional view showing schematically a modified semiconductor device in accordance with the third embodiment.

FIG. 12 is a sectional view showing a structure of a conventional semiconductor device (schottky-gate type transistor).

FIG. 13A is a graph showing electric currents in reverse direction before and after an annealing treatment in each atmosphere.

FIG. 13B is a graph showing heights of schottky barriers before and after the annealing treatment in each atmosphere.

### PREFERRED EMBODIMENTS FOR CARRYING OUT THE INVENTION

Embodiments of the present disclosure are demonstrated hereinafter with reference to the accompanying drawings. Detailed descriptions are sometimes omitted, for instance, well-known matters will not be detailed, and substantially the same structures are not repeatedly described. These omissions will avoid needlessly redundant descriptions, and aid the skilled persons in the art to understand the present disclosure. The accompanying drawings and the descriptions below are exhibited for the skilled persons in the art to fully understand the present disclosure, and these materials do not limit the subject matters disclosed in the claims.

### First Exemplary Embodiment

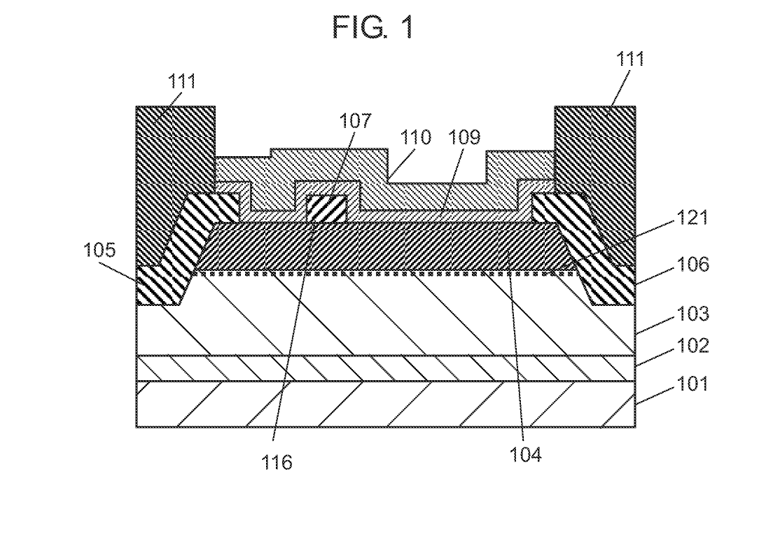

A semiconductor device in accordance with the first embodiment of the present disclosure is demonstrated hereinafter with reference to FIG. 1. This semiconductor device is an FET (Field Effect Transistor). The semiconductor device comprises the following structural elements:

substrate 101 made of Si, of which main surface has plane orientation (111); and

a layered body (semiconductor layer) formed on substrate 101 and including:
buffer layer 102 made of AIN and formed on substrate 101;
carrier transit layer 103 having a layer thickness of 1 μm, made of undoped GaN, and formed on buffer layer 102; and
barrier layer 104 having a layer thickness of 25 nm, made of undoped Al_{0.3}Ga_{0.7}N, and formed on carrier transit layer 103.
   In this context, “undoped” refers to that an impurity is not introduced on purpose, and this definition is applicable to the descriptions below. Buffer layer 102, carrier transit layer 103, and barrier layer 104 have main surfaces of which plane orientations are (0001).

Table 1 shows detailed structures of substrate 101—barrier layer 104, and block layer 108 (described later).

TABLE 1

| | | layer | | conductive | carrier |
|---|---|---|---|---|---|
| | material | thickness | | type | concentration |
| block layer 108 | GaN | 200 | nm | p | 1 × 10¹⁸ cm⁻³ |
| barrier layer 104 | AI_{0.3}Ga_{0.7}N | 25 | nm | undope | — |
| carrier transit | GaN | 1 | μm | undope | — |
| layer 103 | | | | | |
| buffer layer 102 | AIN | 1 | μm | undope | — |
| substrate 101 | Si | 525 | μm | — | — |

Near the interface between carrier transit layer 103 and barrier layer 104, two-dimensional electron gas layer 121 is formed on layer 103 side. To improve the carrier mobility of the two dimensional electron gas, a spacer layer made of AIN and having a layer thickness of 1 nm can be formed between carrier transit layer 103 and barrier layer 104.

Barrier layer 104 is etched at a given place to carrier transit layer 103, so that a recess structure is formed. On this recess structure, source electrode 105 and drain electrode 106, formed of multilayer of Ti and Al, are formed. Gate electrode 107 formed of multilayer of Ni and Au is formed on barrier layer 104, and yet, between source electrode 105 and drain electrode 106. A distance between gate electrode 107 and drain electrode 106 is 3 μm, and a distance between source electrode 105 and gate electrode 107 is 1 μm. A gate length (a width of gate electrode 107 along this paper surface and included in (0001) plane) is 1 μm. In FIG. 1, a length of gate electrode along a direction perpendicular to this paper surface is 100 μm.

In the transistor of this disclosure, source electrode 105 and drain electrode 106 function as ohmic electrodes, and gate electrode 107 functions as a schottky electrode.

First insulating film 109 is formed of silicon nitride film (SiN film) and has a film thickness of 50 nm. This first insulating film 109 has compressive stress and covers the layered body discussed above, source electrode 105, drain electrode 106, and gate electrode 107. Second insulating film 110 is formed of silicon nitride film (SiN film) and has a film thickness of 100 nm. Second insulating film 110 covers a top face of the first insulating film.

First insulating film 109 and second insulating film 110 have openings just above source electrode 105 and drain electrode 106, and these openings are provided with wirings 111 made of Au.

A hydrogen concentration of first insulating film 109 is not greater than 1×10²¹ cm⁻³, and that of second insulating film 110 is 2×10²² cm⁻³, so that first insulating film 109 has a smaller hydrogen concentration than second insulating film 110.

Table 2 shows detailed structures of first insulating film 109 and second insulating film 110.

TABLE 2

| | | | hydrogen |
|---|---|---|---|
| | | layer | concentration |
| | material | thickness | [cm⁻³] |
| first insulating film 109 | SiN | 50 nm | ≦1 × 10²¹ |
| second insulating film 110 | SiN | 100 nm | 2 × 10²² |

Method for Manufacturing the Semiconductor Device in Accordance with the First Embodiment

The method for manufacturing the semiconductor device in accordance with the first embodiment is outlined hereinafter.

First, buffer layer 102, carrier transit layer 103, and barrier layer 104 are formed on substrate 101 by MOVPE (metal organic vapor phase epitaxy) method. Then gate electrode 107, source electrode 105, and drain electrode 106 are formed by a sputtering method or a depositing lift-off method.

Next, first insulating film 109 is formed such that film 109 can cover source electrode 105, drain electrode 106, and gate electrode 107. First insulating film 109 is formed by a sputtering method using, for instance, argon gas, or mixed gas of nitrogen gas and argon gas. Use of this method allows decreasing an amount of hydrogen produced during the film deposition, so that film 109 contains a small amount of hydrogen per unit volume.

Then second insulating film 110 is formed on first insulating film 109. This second insulating film 110 is formed by the P-CVD method using silane gas and ammonium gas.

Next, an opening is formed on each of first insulating film 109 and second insulating film 110 at positions corresponding to source electrode 105 and drain electrode 106, and then these openings are provided with wirings 111 made of Au.

The structure discussed above allows first insulating film 109 to have a smaller concentration of hydrogen per unit volume than that of second insulating film 110, thereby reducing advantageously a gate leakage current. In other words, the schottky electrode is covered with the insulating film that contains a small amount of hydrogen per unit volume, and this structure prevents hydrogen from entering the interface between the metal and the semiconductor. As a result, the leakage current can be prevented from increasing.

The structure discussed above also allows first insulating film 109 to prevent hydrogen from entering the interface between the metal and the semiconductor when second insulating film 110 is formed because first insulating film 109 contains a less amount of hydrogen per unit volume. As a result, a semiconductor device having a smaller amount of leakage current can be obtained.

In this embodiment, source electrode 105 and drain electrode 106 are in ohmic contact with 2DEG electron gas layer 121. These electrodes 105 and 106 are formed such that they can cover the recess structure, which breaks through barrier layer 104. Electrodes 105 and 106 undergo an annealing treatment to be brought into contact with 2DEG electron gas layer 121. The recess structure can be formed somewhere in barrier layer 104, but it is not always needed.

The inventors have studied an insulating film of SiN about differences in concentrations of hydrogen contained therein (hydrogen content) depending on methods for depositing films. The concentrations of hydrogen are measured by the FT-IR (Fourier Transform Infrared Spectroscopy) method. Table 3 shows relations between samples of SiN film and hydrogen content.

TABLE 3

| | Method for depositing | |
|---|---|---|
| Sample | SiN film | Hydrogen content [1/cm³] |
| sample A | P-CVD | 2.2 − 2.4 × 10²² |
| sample B | P-CVD + 800° C. anneal | 8.5 × 10²¹ |
| sample C | ECR sputtering | Detection limit ≦ (1 × 10²¹) |
| sample D | Low pressure CVD | 4.1 × 10²¹ |

In table 3, sample A is a SiN film formed by the P-CVD method, sample B is a SiN film formed by the P-CVD method and then having undergone an annealing treatment at 800° C. Sample C is a SiN film formed by the ECR sputtering method, and sample D is a SiN film formed by the Low pressure CVD method. The ECR sputtering shown in table 3 refers to a sputtering method using ECR (electron cyclotron resonance), and P-CVD+800° C. anneal in table 3 refers to the processes of P-CVD and anneal at 800° C. after the P-CVD. The Low pressure CVD refers to a CVD done at a pressure lower than the atmospheric pressure.

Table 3 shows that sample C formed by the sputtering method contains a least amount of hydrogen, and the result of sample B proves that the annealing treatment can reduce the hydrogen content.

### First Modification of the First Embodiment

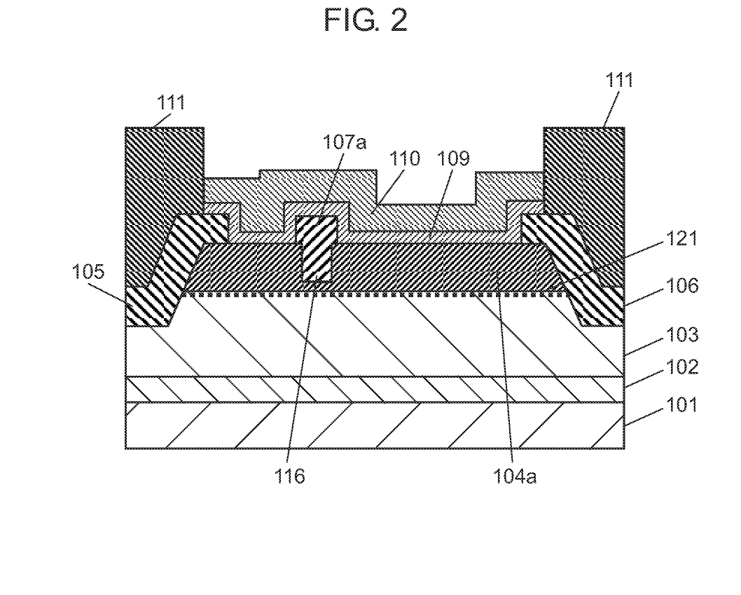

A semiconductor device of a first modification in accordance with the first embodiment is demonstrated hereinafter with reference to FIG. 2. This semiconductor device is an FET. This first modification differs in a structure of the gate electrode from the semiconductor device in accordance with the first embodiment and shown in FIG. 1. To be more specific, in this first modification, barrier layer 104a that is a part of a gate region undergoes the etching process for forming recess 116, so that a film thickness at recess 116 becomes thinner, and gate electrode 107a is so formed as fitting into recess 116. The structures of substrate 101—barrier layer 104, including a material, a conductive type, and other structures, stay the same as those shown in table 1.

The foregoing structure allows achieving better controllability of the gate than that of the semiconductor device shown in FIG. 1. At the place of the gate electrode, the etching can be done further down to carrier transit layer 103 for forming recess 116. This structure allows a normally-off action to be done.

### Second Modification of the First Embodiment

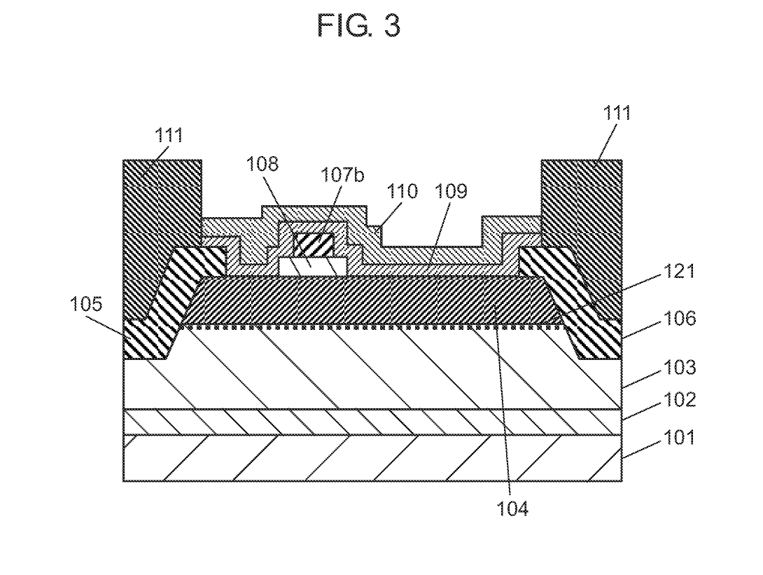

A semiconductor device of a second modification in accordance with the first embodiment is demonstrated hereinafter with reference to FIG. 3. This semiconductor device is an FET. This second modification differs in block layer 108 from the semiconductor device in accordance with the first embodiment and shown in FIG. 1. This block layer 108 is disposed between gate electrode 107b and barrier layer 104. To be more specific, block layer 108 has a film thickness of 200 nm and is formed of GaN of which carrier concentration is 1×10¹⁸ cm⁻³ by Mg-doping. The structures of substrate 101—barrier layer 104 stay the same as those shown in table 1.

The presence of block layer 108 allows achieving a smaller leakage current of the modified semiconductor device than that of the semiconductor device shown in FIG. 1

### Third Modification of the First Embodiment

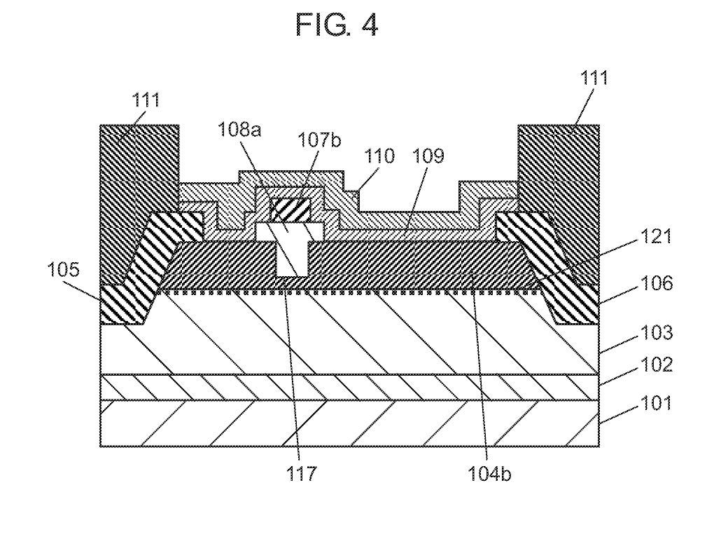

A semiconductor device of a third modification in accordance with the first embodiment is demonstrated hereinafter with reference to FIG. 4. This semiconductor device is an FET.

The semiconductor device in accordance with this third modification differs in block layer 108a fitting into recess 117 from the semiconductor device in accordance with the second modification and shown in FIG. 3. Block layer 108a is formed in recess 117 that is formed by etching barrier layer 104b which is a part of the gate region. Block layer 108a has the same structures including a composition, conductive type, and carrier concentration as those of the foregoing second modification. The structures of substrate 101—barrier layer 104 stay the same as those shown in table 1.

The structure discussed above allows achieving a smaller leakage current of the semiconductor device than that of the semiconductor device shown in FIG. 1 due to the presence of block layer 108, and also achieving better controllability of the gate than the semiconductor device shown in FIG. 3, and allows the normally-off action to be done due to a thinner barrier layer.

In the semiconductor devices in accordance with the first embodiment and the first to third modifications, and the methods for manufacturing the semiconductor devices in accordance with the first embodiment, source electrode 105 and drain electrode 106 are not limited to a multilayer structure formed of Ti and Al, but other metals such as Hf, W, V, Mo, Au, Ni, Nb can be used.

Gate electrodes 107, 107a, and 107b are not limited to the multilayer structure formed of Ni and Au, but those electrodes can employ a single layer or a multilayer contains at least one of Ni, Pd, Au, and Ti.

The method for manufacturing first insulating film 109 is not limited to the sputtering method, but the P-CVD method or an ALD (atomic layer deposition) method can be used as long as they can reduce an amount of hydrogen content. A material for first insulating film 109 can employ nitrogen gas or argon gas.

### Second Exemplary Embodiment

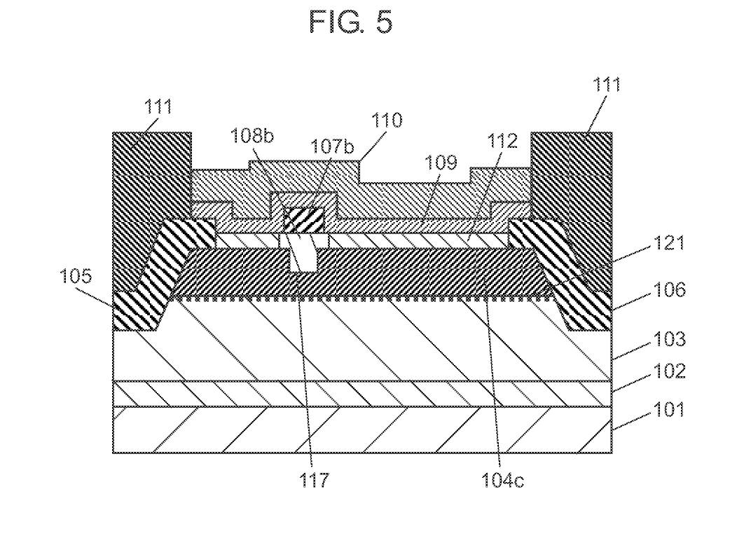

A semiconductor device in accordance with the second embodiment is demonstrated hereinafter with reference to FIG. 5. This semiconductor device is an FET. The semiconductor device in accordance with the second embodiment comprises substrate 101 and barrier layer 104c, and between them there are source electrode 105, drain electrode 106, gate electrode 107b, first insulating film 109, and second insulating film 110. These structural elements stay the same as those of the semiconductor device in accordance with the first embodiment. In this second embodiment, barrier layer 104c, which is a part of a gate region, is etched to form a recess 119 so that a film thickness there is reduced, and block layer 108b is formed to fit into recess 119. A composition, a conductive type, and a carrier concentration of block layer 108b stay the same as those of the second and third modifications of the first embodiment. Block layer 108b is formed between gate electrode 107b and barrier layer 104c.

This semiconductor device differs from that of the first embodiment in a presence of third insulating film 112 formed between first insulating film 109 and barrier layer 104c. This third insulating film 112 is formed of silicon nitride film having a film thickness of 50 nm, and covers block layer 108b. An upper part of block layer 108b is opened for forming gate electrode 107. This structure allows achieving a smaller amount of leakage current than that of the structures having no block layer 108b. Table 4 shows detail specifications of first, second, and third insulating films 109, 110, and 112.

TABLE 4

| | | | hydrogen |
|---|---|---|---|
| | | film | concentration |
| | material | thickness | [cm⁻³] |
| first insulating film 109 | SiN | 50 nm | ≦1 × 10²¹ |
| second insulating film 110 | SiN | 100 nm | 2 × 10²² |
| third insulating film 112 | SiN | 50 nm | ≦1 × 10²² |

Since the hydrogen concentration per unit volume of third insulating film 112 is smaller than that of second insulating film 110, the gate leakage current can be advantageously reduced. In other words, parts of an upper side and a lower side of the schottky electrode is covered with the insulating film having a smaller hydrogen content, whereby hydrogen can be prevented from entering the interface between the metal and the semiconductor. As a result, the leakage current can be prevented from increasing.

### Method for Manufacturing the Semiconductor Device of the Second Embodiment

The manufacturing method is outlined hereinafter. On substrate 101, buffer layer 102, carrier transit layer 103, and barrier layer 104c are formed, a recess is formed in barrier layer 104c, and block layer 108b is formed in the recess. The foregoing procedure stays the same as that of the first embodiment.

Third insulating film 112 is formed such that it covers barrier layer 104c and block layer 108b. Then an upper section of block layer 108b and a region where the ohmic electrode is formed are etched to form an opening. A gate electrode is formed on an upper section of block layer 108b positioned at the opening of third insulating film 112. A source electrode and a drain electrode are formed on barrier layer 104c positioned at the opening of third insulating film 112.

The manufacturing step of forming third insulating film 112 such that it can cover barrier layer 104c differs greatly from the manufacturing method in the first embodiment. Third insulating film 112 is made of silicon nitride film having a film thickness of 50 nm. This silicon nitride film is formed by the P-CVD method using silane-based gas together with ammonia gas or nitrogen gas. However, in order to reduce the hydrogen content, this film can be provided with an annealing treatment at 500° C. or higher after depositing the film, or after providing the gate region or the ohmic-electrode forming region with an opening. Third insulating film 112 can be formed by the sputtering method because the sputtering method can reduce the hydrogen content. As table 3 shows, the annealing treatment will reduce the hydrogen concentration from 2×10²² cm⁻³ to 8.5×10²¹ cm⁻³, namely, the concentration is lowered to less than a half of the original one. In the case of forming a gate recess or an ohmic recess, it can be done either before or after third insulating film 112 is formed. Third insulating film 112 can be made of aluminum nitride. In the case of employing the sputtering method, argon gas, nitrogen gas, or mixed gas of argon gas and nitrogen gas can be used for depositing the film.

The opening of third insulating film 112 in the gate region is formed at a place where the upper section of block layer 108b is disposed. The opening of the ohmic-electrode forming region is formed at a place where source electrode 105 and drain electrode 106 are disposed on a top face of barrier layer 104c.

Next, first insulating film 109 is formed such that it covers third insulating film 112, source electrode 105, drain electrode 106, and gate electrode 107b. This first insulating film 109 is formed by the sputtering method using mixed gas of nitrogen gas and argon gas. However, the method is not limited to the sputtering method, for instance, the P-CVD method or the ALD method can be employed as long as these methods can reduce the hydrogen content.

Then second insulating film 110 is formed on first insulating film 109. This film 110 is formed by the P-CVD method using silane gas and ammonia gas.

Next, an opening is formed on each of first insulating film 109 and second insulating film 110 at a place corresponding to source electrode 105 and drain electrode 106, and then each of the openings is provided with wiring 111 made of Au.

The structure discussed above allows third insulating film 112 to have a smaller hydrogen concentration per unit volume than second insulating film 110, so that the gate leakage current can be reduced advantageously. During the formation of second insulating film 110, this third insulating film 112 allows preventing hydrogen from entering the interface between the metal and the semiconductor because film 112 contains a smaller amount of hydrogen. As a result, the semiconductor device having a smaller amount of leakage current is obtainable.

### Modification Example

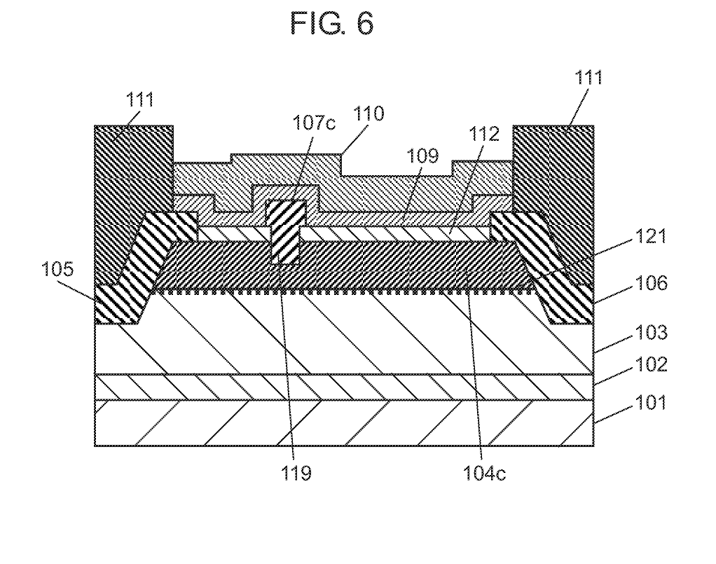

A semiconductor device modified from the semiconductor device in accordance with the second embodiment is demonstrated hereinafter with reference to FIG. 6. This modified sample is an FET, and differs from the semiconductor device in accordance with the second embodiment shown in FIG. 5 in a gate electrode. To be more specific, gate electrode 107c replaces block layer 108b and is formed in recess 119 that is formed in barrier layer 104c.

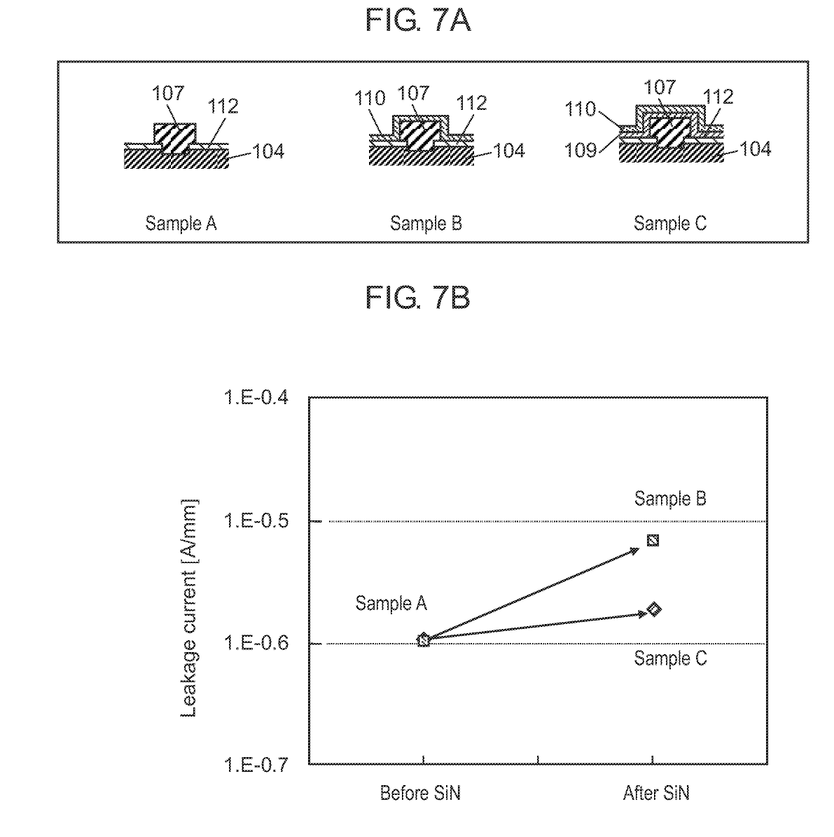

FIG. 7A and FIG. 7B show leakage properties of the modification samples shown in FIG. 6 and leakage properties of the modification samples having no first insulating films 109. To be more specific, FIG. 7A shows structures of the modification samples A-C, and FIG. 7B shows leakage properties of each one of the modification samples. Sample A is a semiconductor device having only third insulating film 112 (i.e. the semiconductor device before first and second insulating films 109 and 110 are formed). Sample B includes first and second insulating films 109 and 110. Sample C includes first, second and third insulating films 109, 110, and 112. First insulating film 109 has a film thickness of 50 nm. Second insulating film 110 has a film thickness of 50 nm in sample C, and 100 nm in sample B. Third insulating film 112 has a film thickness of 50 nm in each of samples A-C. Each of samples B and C thus has a total film thickness of 150 nm. Table 5 shows film thicknesses of samples A-C.

TABLE 5

| | Sample A | Sample B | Sample C |
|---|---|---|---|
| first insulating film109 | — | — | 50 nm |
| second insulating film 110 | — | 100 nm | 50 nm |
| third insulating film 112 | 50 nm | 50 nm | 50 nm |

In FIG. 7B, the data are taken by plotting leakage currents when 100V is applied between the gate and the drain. In FIG. 7B, for instance, 1.E-07 is marked along the vertical axis, where E represents a power of ten, namely, 1.E-07 refers to 1×10⁻⁷, and FIG. 7B shows a semi-logarithmic graph of which vertical axis is expressed in A/mm units. In FIG. 7B, “before SiN” refers to before first insulating film 109 or second insulating film 110 is formed (sample A), and “after SiN refers to after first insulating film 109 or second insulating film 110 is formed (sample B or C).

FIG. 7B shows that the structure having no first insulating film 109 (i.e. sample B) encounters the leakage current as much as 6.7 times that of the structure in which first and second insulating films 109 and 110 are not yet formed (i.e. sample A); however, the structure of the present disclosure (i.e. sample C) encounters the leakage current as little as 1.8 times that of the structure in which first and second insulating films 109 and 110 are formed (i.e. sample A). This fact proves that the covering the gate electrode with first insulating film 109 allows preventing the hydrogen that is produced in depositing second insulating film 110 from entering the gate electrode, so that the leakage current can be prevented from increasing.

The film thickness of first insulating film 109 is increased from 50 nm to 100 nm, thereby further reducing the leakage current.

In the semiconductor devices in accordance with the second embodiment and modified examples thereof, and in a method for manufacturing them, barrier layer 104c can employ other compositions than Al_{0.3}Ga_{0.7}, such as AlN, AlₓGa₁₋ₓN (0<x<1), or AlₓGa_{1-x-y}In_{y}N (0≦x≦1, 0≦y≦1). Barrier layer 104c also can employ a multilayer structure or a super-lattice structure of AlN/GaN, a multilayer structure or a super-lattice structure of AlN/AlₓGa₁₋ₓN (0<x<1), or a multilayer structure or a supper-lattice structure of GaN/AlₓGa₁₋ₓN (0<x<1).

Source electrode 105 and drain electrode 106 can employ not always a multilayer structure formed of Ti and Al, but it can employ other metals instead, for instance, Hf, W, V, Mo, Au, Ni, Nb and so on. Gate electrodes 107b, 107c can employ not always multilayer structure of Ni and Au, but they can employ a single layer or a multilayer including at least one of Ni, Pd, Au, Ti.

Third insulating film 112 used in the second embodiment can be inserted between gate electrode 107b and a nitride semiconductor (i.e. barrier layer 104c shown in FIGS. 5 and 6), so that the semiconductor device can be an insulating gate type nitride semiconductor device.

The phenomenon of hydrogen arriving at the interface between metal and semiconductor and reacting thereto can be observed not only in nitride semiconductors but also in compound semiconductors, so that the structure used in the second embodiment can be applied to the compound semiconductors typically represented by GaAs or InP with the same advantage.

The structure disclosed in the second embodiment and its modification example allow reducing off-leak current without degrading ON characteristics, so that the nitride semiconductor transistor having a low leak with a low ON resistance is obtainable.

### Third Exemplary Embodiment

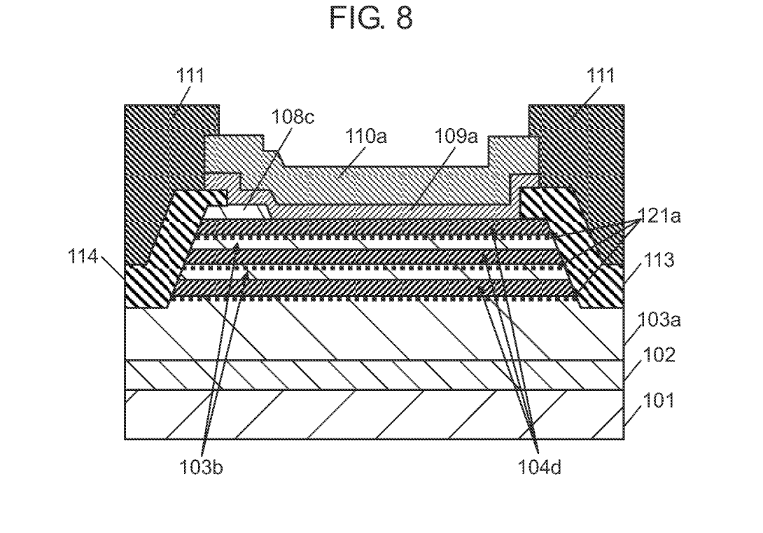

A semiconductor device in accordance with the third embodiment is demonstrated hereinafter with reference to FIG. 8. This device is a schottky diode (SD).

The semiconductor device in accordance with the third embodiment includes Si substrate 101 of which main surface has a plane orientation of (111). On substrate 101, the following layers are formed sequentially: buffer layer 102 made of AlN, first carrier transit layer 103a made of undoped GaN and having a layer thickness of 1 μm, and barrier layer 104d made of Al_{0.25}Ga_{0.75}N and having a layer thickness of 25 nm. On top of this structure, second carrier transit layer 103b made of undoped GaN and having a layer thickness of 220 nm and barrier layer 104d made of undoped Al_{0.25}Ga_{0.75}N and having a layer thickness of 25 nm are alternately formed in two cycles or more, and block layer 108c is formed partially on the upper most barrier layer 104d. FIG. 8 shows the alternate layers in three cycles. To be more specific, block layer 108c is made of GaN doped with Mg, and having a carrier concentration of 1×10¹⁸ cm⁻³ and a layer thickness of 200 nm. Buffer layer 102, first carrier transit layer 103a, barrier layer 104d, and block layer 108c have main surfaces of which plane orientations are (0001).

Two-dimensional electron gas layer 121a is formed near an interface between carrier transit layer 103a and barrier layer 104d (on layer 103a side), and it is also formed near an interface between second carrier transit layer 103b and barrier layer 104d (on layer 103b side). In other words, one gas layer 121a is formed for first carrier transit layer 103a, and one gas layer 121a is formed for one second carrier transit layer 103b, so that multiple two-dimensional electron gas layers 121a in total are formed.

Structures of substrate 101—barrier layer 104d, block layer 108c, and second carrier transit layer 103b are summarized in table 6.

TABLE 6

| | | layer | | conductive | carrier |
|---|---|---|---|---|---|
| | material | thickness | | type | concentration |
| block layer 108c | GaN | 200 | nm | p | 1 × 10¹⁸ cm⁻³ |
| 2^{nd} carrier transit | GaN | 220 | nm | undope | — |
| layer 103b | | | | | |
| barrier layer 104d | AI_{0.25}Ga_{0.75}N | 25 | nm | undope | — |
| 1^{st} carrier transit | GaN | 1 | μm | undope | — |
| layer 103 a | | | | | |
| buffer layer 102 | AIN | 1 | μm | undope | — |
| substrate 101 | Si | 525 | μm | — | — |

The upper most barrier layer 104d is etched as deep as to the lower most first carrier transit layer 103d at a given place for forming a recess structure, and cathode electrode 113 formed of multi-films made of Ti and Al is formed onto this recess structure. Block layer 108c is also etched as deep as to the lower most first carrier transit layer 103d at a place different from cathode electrode 113 for forming another recess structure, and anode electrode 114 formed of multi-films made of Ni and Au is formed onto this recess structure. Cathode electrode 113 is apart from anode electrode 114 by 10 μm.

In the diode disclosed here, cathode electrode 113 discussed above functions as an ohmic electrode, and anode electrode 114 discussed above functions as a schottky electrode.

First insulating film 109a is made of silicon nitride film (SiN film) and has a film thickness of 100 nm. This first insulating film 109a covers barrier layer 104d, block layer 108c, cathode electrode 113, and anode electrode 114.

Second insulating film 110a is made of silicon nitride film (SiN film) and has a film thickness of 900 nm. This second insulating film 110a covers first insulating film 109a.

Just above cathode electrode 113 and anode electrode 114, openings are formed in first insulating film 109a and second insulating film 110a, and the openings are provided with wirings 111 made of Au.

First insulating film 109a has a hydrogen concentration of 1×10²¹ cm⁻³ or less, and second insulating film 110a has a hydrogen concentration of 2×10²² cm⁻³, so that the hydrogen concentration of first insulating film 109a is smaller than that of second insulating film 110a.

Method for Manufacturing the Semiconductor Devices in accordance with the Third Embodiment

The manufacturing method of the semiconductor devices of the third embodiment is outlined hereinafter. First, buffer layer 102, first carrier transit layer 103a, barrier layer 104d, second carrier transit layer 103b, and block layer 108c are formed on substrate 101 by the MOVPE method. Block layer 108c is removed by etching after crystal growth with a given region remaining.

Next, cathode electrode 113 and anode electrode 114 are formed by a depositing lift-off method or a sputtering method. Then first insulating film 109a is formed such that it covers cathode electrode 113 and anode electrode 114. This first insulating film 109a is formed by the sputtering method using mixed gas of nitrogen gas and argon gas.

Next, second insulating film 110a is formed on first insulating film 109a by a P-CVD method using silane gas and ammonium gas.

Then first and second insulating films 109a and 110a are provided with openings at places corresponding to cathode electrode 113 and anode electrode 114, and then wirings 111 made of Au are formed in the openings.

The structure discussed above allows first insulating film 109a has a hydrogen concentration per unit volume smaller than that of second insulating film 110a, thereby advantageously reducing the leakage current. The structure discussed above also allows first insulating film 109a to prevent hydrogen from entering the interface between the metal and the semiconductor during the formation of second insulating film 110a because first insulating film 109a contains a less amount of hydrogen per unit volume. As a result, a semiconductor device having a smaller amount of leakage current can be obtained.

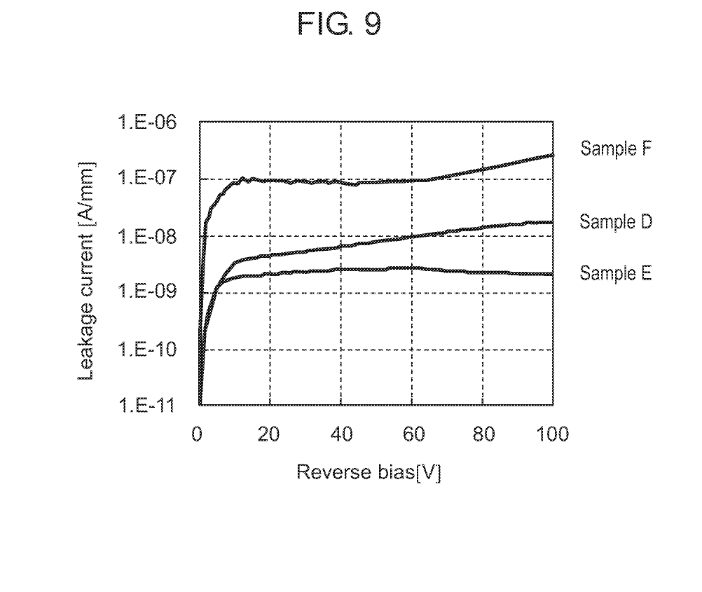

FIG. 9 is a graph showing structures of the semiconductor devices in accordance with the third embodiment and shown in FIG. 8, and reverse-directional leakage characteristics of the diode which employs only second insulating film 110a. In FIG. 9, the horizontal axis represents values of reverse bias (i.e. the cathode is at a positive voltage and the anode is at a reference voltage (GND) in units of volts), and the vertical axis represents values of leakage current in units of amperes/mm. In FIG. 9, for instance, 1.E-07 is marked along the vertical axis, where E represents a power of ten, namely, 1.E-07 refers to 1×10⁻⁷. FIG. 9 shows a semi-logarithmic graph.

Sample D of the diode in FIG. 9 employs first insulating film 109a made of silicon nitride film (expressed as ECR-SiN film) having a film thickness of 100 nm and formed by ECR sputtering method, and second insulating film 110a made of silicon nitride film (expressed as P—SiN film) having a film thickness of 900 nm and formed on first insulating film 109a by the P-CVD method.

Sample E of the diode in FIG. 9 employs first insulating film 109a made of aluminum nitride film (AlN film) having a film thickness of 50 nm and formed by the ECR sputtering method, and second insulating film 110a made of silicon nitride film (expressed as P—SiN film) having a film thickness of 900 nm and formed by the P-CVD method on first insulating film 109a. Sample F of the diode employs only second insulating film 110a made of silicon nitride film formed by the P-CVD method. Sample F is built for comparison purpose. The structures of the insulating films of samples D-F are listed in table 7.

TABLE 7

| | AIN film | ECR-SiN film | P-SiN film |
|---|---|---|---|
| Sample D | — | 100 nm | 900 nm |
| Sample E | 50 nm | — | 900 nm |
| Sample F | — | — | 1000 nm |

As FIG. 9 clearly shows, use of the structure in accordance with the third embodiment shown in FIG. 8 allows reducing the leakage current by as much as 10 times or more. In this connection, a component of the leakage current produced in the structure shown in FIG. 8 includes a leakage from the schottky junction formed of anode electrode 114 and the nitride semiconductor (barrier layer 104d and carrier transit layer 103b), and a leakage through block layer 108c formed of p-AlGaN and disposed under anode electrode 114. The leakage characteristics of sample F that employs only silicon nitride film 110a formed by the PCVD method show that the leakage current through block layer 108c starts increasing from around 60V; however, the structure shown in FIG. 8 does not show a sharp increase in the leakage current.

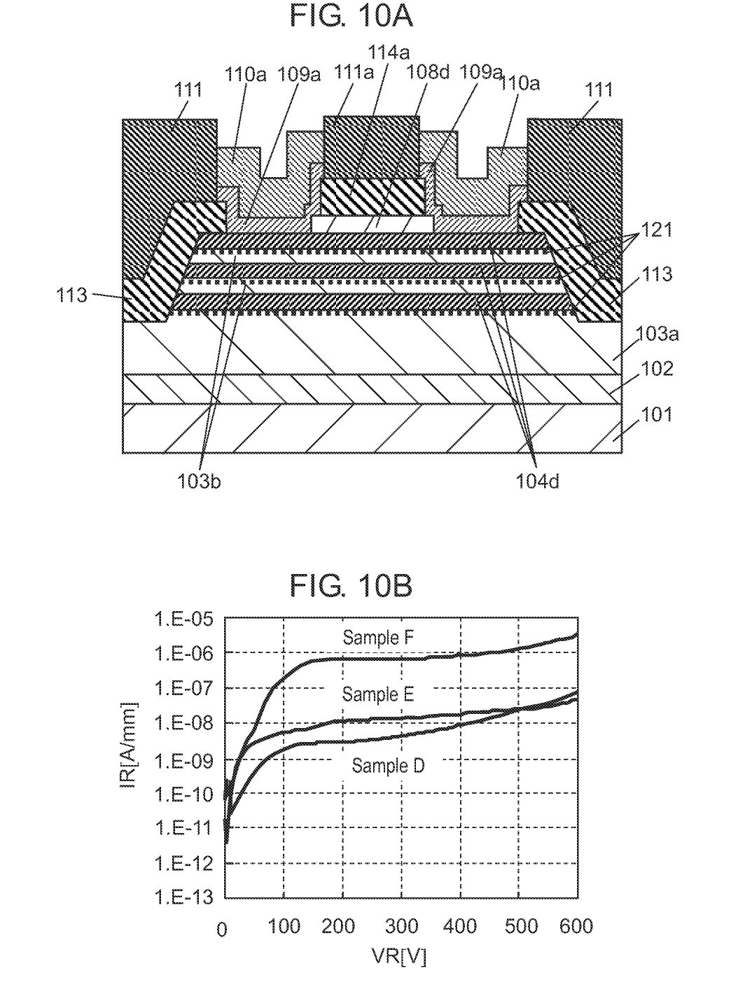

To examine components of the leakage through block layer 108c, the structure shown in FIG. 10A is evaluated. This structure does not have the anode recess shown in FIG. 8. In this structure shown in FIG. 10A, anode electrode 114a is disposed above barrier layer 104d via block layer 108d, and wiring 111a is formed on anode electrode 114a. In other words, since anode electrode 114a is not in contact with the nitride semiconductor (i.e. barrier layer 104d and carrier transit layer 103d), the leakage from the schottky junction can be excluded, so that only the leakage through block layer 108d can be evaluated.

The evaluation result is shown as a graph in FIG. 10B. The materials for and thicknesses of the insulating films stay the same as those shown in table 7. In the graph shown in FIG. 10B, the horizontal axis represents values of reverse bias (i.e. the cathode is at a positive voltage and the anode is at a reference voltage (GND) in units of volts), and the vertical axis represents values of leakage current IR in units of amperes/mm. In FIG. 10B, for instance, 1.E-07 is marked along the vertical axis, where E represents a power of ten, namely, 1.E-07 refers to 1×10⁻⁷. FIG. 10B shows a semi-logarithmic graph.

FIG. 10B shows that the leakage through block layer 108d is greater in the sample employing only silicon-nitride film 110a formed by the P-CVD method, and the sample employing the structure disclosed in this disclosure reduces the leakage current by as much as approx. 100 times. As a result, the structure shown in FIG. 10A not only reduces the leakage from the schottky junction but also reduces the leakage current through block layer 108d.

A diode of 3-channel is taken as an example here; however, an advantage similar to what is discussed above can be observed in a diode of a greater or smaller number of channels.

The structure disclosed in this third embodiment can reduce the leakage current in reversal direction without degrading the forward direction characteristics of the semiconductor device, so that a nitride semiconductor diode having a less amount of leakage current in reversal direction with a low ON resistance is obtainable.

### Modification Example

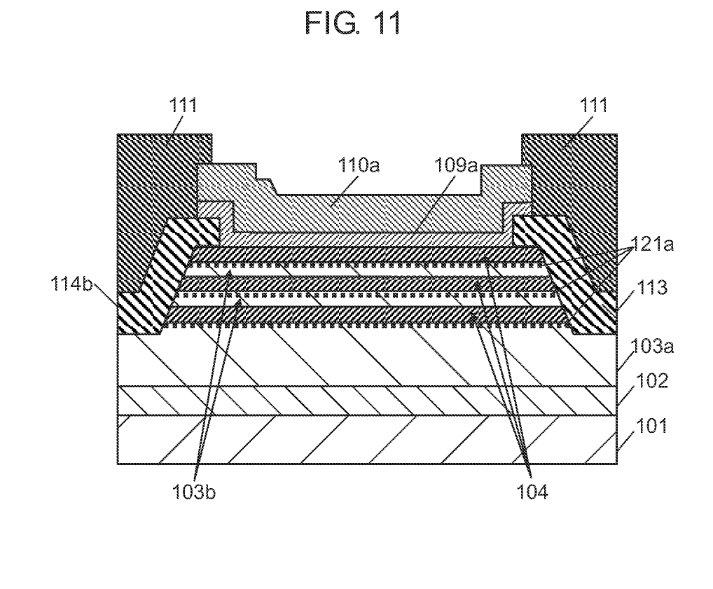

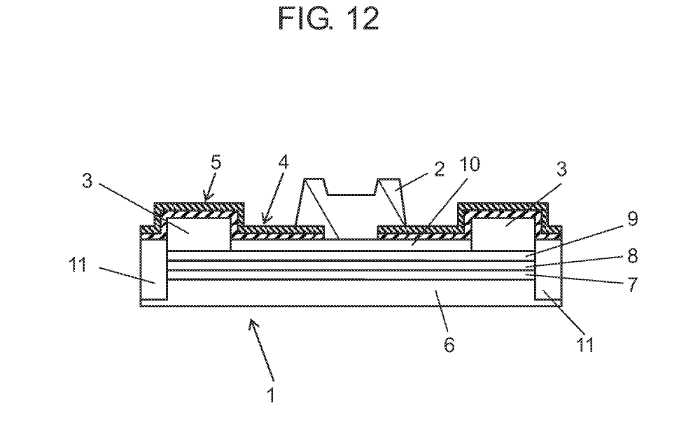

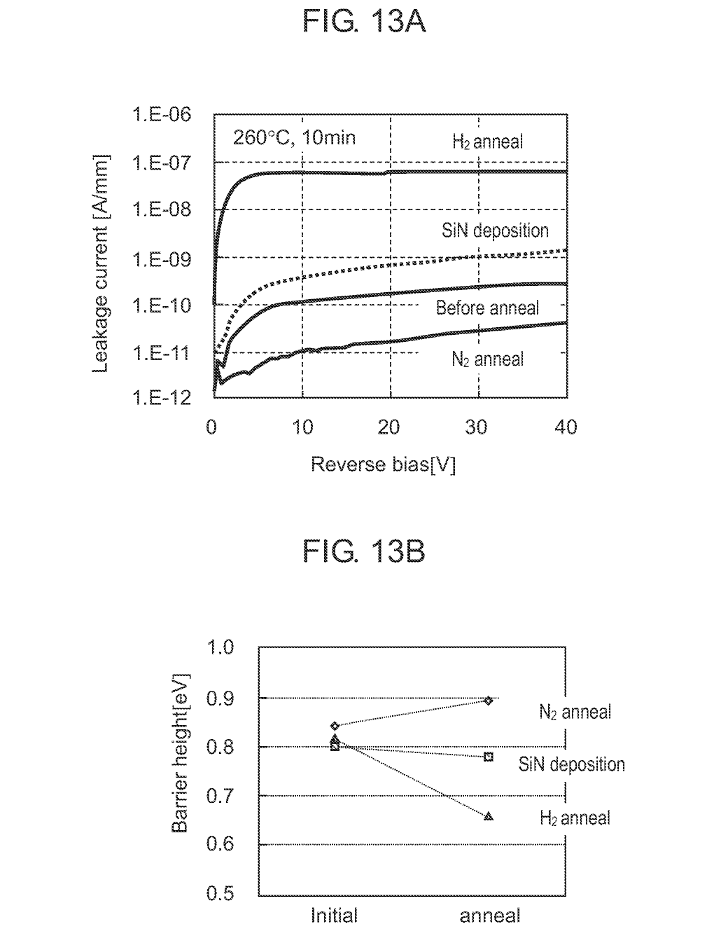

A modified semiconductor device in accordance with the third embodiment is demonstrated hereinafter with reference to FIG. 11. This semiconductor device is a schottky diode (SD). This modified semiconductor device differs in the anode electrode from the semiconductor device shown in FIG. 8 and in accordance with the third embodiment. To be more specific, in this modification example, block layer 108c or 108d is not formed, and anode electrode 114b is directly formed on the main surface of the upper most barrier layer 104d.

This structure also allows reducing the leakage current in reversal direction without degrading the forward direction characteristics, so that a nitride semiconductor diode having a less amount of leakage current in reversal direction with a low ON resistance is obtainable. A diode of 3-channel is taken as an example in this modification example; however, an advantage similar to what is discussed above can be observed in a diode of a greater or smaller number of channels.

In the third embodiment and its modification example, the composition of second carrier transit layer 103b is not limited to the foregoing one. Second carrier transit layer 103b can employ not always GaN, but it can employ AlₓGa₁₋ₓN (0<x≦1) or AlₓGa_{1-x-y}In_{y}N (0≦x≦1, 0≦y≦1) instead. The composition of first carrier transit layer 103a can be different from that of second carrier transit layer 103b. Second carrier transit layer 103b is formed of a multilayer, and each layer of the multilayer can have a different composition.

Barrier layer 104d can be formed of not always Al_{0.25}Ga_{0.75}N but it can be formed of AlN, or having another composition such as AlₓGa₁₋ₓN (0<x<1) or AlₓGa_{1-x-y} In_{y}N (0≦x≦1, 0≦y≦1). Barrier layer 104d can also employ a multilayer structure or super-lattice structure of AlN/GaN, a multilayer structure or super-lattice structure of AlN/AlₓGa₁₋ₓN (0<x<1), or a multilayer structure or super-lattice structure of GaN/AlₓGa₁₋ₓN (0<x<1).

Cathode electrode 113 is not limited to a multilayer structure formed of Ti and Al, but other metals such as Hf, W, V, Mo, Au, Ni, Nb can be used.

Anode electrodes 114, 114a, 114b are not limited to multilayer structures of Ni and Au, but each of these anode electrodes can be formed of a single layer or a multilayer containing at least one of Ni, Pd, Au, and Ti.

In each of the embodiments and each of their modification examples discussed previously, substrate 101 can employ not always Si substrate but it can employ GaN substrate, sapphire substrate, or spinel substrate instead. The plane orientation of substrate 101 is not limited to (111) plane, but (001) plane can be used instead. In the case of employing a hexagonal crystal substrate such as GaN substrate or sapphire substrate, plane c namely (0001) plane is chiefly used; however, plane m or plane r can be used instead. The thickness of substrate 101 is not limited to 525 μm.

Buffer layer 102 preferably has a thickness of 1-5 μm, and carrier transit layer 103 (103a) preferably has a thickness of 1-3 μm. Barrier layer 104 (104a, 104b, 104c, and 104d) preferably has a thickness falling within a range of 1-80 nm. This range includes both the ends (i.e. not less than 1 nm and not more than 80 nm).

Block layer 108 (108a, 108b, 108c, and 108d) preferably has a thickness falling within a range of 50-200 nm. Block layer 108 is formed of not always GaN but it can be formed of AlₓGa₁₋ₓN (0<x≦1) or AlₓGa_{1-x-y}In_{y}N (0≦x≦1, 0≦y≦1). The carrier concentration of block layer 108 is not limited to 1×10¹⁸ cm⁻³, but it can be set to an value appropriate to characteristics of a semiconductor device.

Block layer 108 employs p-type GaN; however, as long as the layer forms a p-type layer, an oxide semiconductor layer (e.g. NiO) or an organic semiconductor layer can be employed instead of GaN.

The compositions of buffer layer 102, carrier transit layer 103, and barrier layer 104 are not limited to those discussed above. For instance, buffer layer 102 can be formed of not always AlN, but it can be formed of GaN, AlₓGa₁₋ₓN (0<x≦1) or AlₓGa_{1-x-y} In_{y}N (0≦x≦1, 0≦y≦1). Buffer layer 102 can also employ a multilayer structure or super-lattice structure of AlN/GaN, a multilayer structure or super-lattice structure of AlN/AlₓGa₁₋ₓN (0<x<1), or a multilayer structure or super-lattice structure of GaN/AlₓGa₁₋ₓN (0<x<1).

Carrier transit layer 103 (103a) can be formed of not always GaN but it can be formed of AlₓGa₁₋ₓN (0<x≦1) or AlₓGa_{1-x-y}In_{y}N (0≦x≦1, 0≦y≦1).

First insulating film 109 (109a) and second insulating film 110 (110a) can be not always formed of silicon nitride film, and they can be formed of aluminum nitride (AIN) film or silicon oxynitride (SiON) film. Second insulating film 110 can be formed of silicon oxynitride film, or a multilayer film of silicon oxide film and silicon nitride film. The film thicknesses of first insulating film 109 and second insulating film 110 are not limited to the foregoing ones, but the thicknesses can be set appropriately to characteristics of semiconductor devices. The concentrations and film thicknesses of each one of the structural elements including first and second insulating films are not limited to the ones discussed previously, and they can be set appropriately.

The first to the third embodiments and their modification examples are demonstrated hereinbefore as examples of the techniques disclosed in this patent application; however, the techniques in the present disclosure are not limited to those embodiments or modification examples, and the techniques are applicable to other embodiments in which changes, replacements, additions, or omissions take place appropriately.

The exemplary embodiments and their modification examples are demonstrated hereinbefore as examples of the techniques disclosed in this disclosure, and the accompanying drawings as well as detailed descriptions are provided for this purpose. The structural elements described in the accompanying drawings and the detailed descriptions include not only essential elements for solving the problem but also not-essential elements. The not-essential elements however should not be construed as the essential elements on the ground of being put in the accompanying drawings and detailed descriptions.

Since the exemplary embodiments and their modification examples are demonstrated hereinbefore as examples of the techniques disclosed in this disclosure, various changes, replacements, additions, and omissions can be done in the scope of claims or in equivalent scopes.

### INDUSTRIAL APPLICABILITY

The semiconductor device disclosed in the present disclosure is useful as a power device to be used in power-supply circuits or high-frequency devices of consumer apparatuses including television receivers.

### REFERENCE MARKS IN DRAWINGS

101 substrate
102 buffer layer
103, 103a, 103b carrier transit layer
104, 104a, 104b, 104c, 104d barrier layer
105 source electrode
106 drain electrode
107, 107a, 107c gate electrode
108, 108a, 108b, 108c, 108d block layer
109, 109a first insulating film
110, 110a second insulating film
111, 111a wiring
112 third insulating film
113 cathode electrode
114, 114a, 114b anode electrode
121, 121a two-dimensional electron gas layer

1. A semiconductor device comprising:
a semiconductor layer;
an ohmic electrode formed on the semiconductor layer;
a schottky electrode formed on the semiconductor layer;
a first insulating film covering a place of the semiconductor layer between the ohmic electrode and the schottky electrode, and the schottky electrode that forms a schottky junction with the semiconductor layer; and
a second insulating film formed on the first insulating film and containing a greater amount of hydrogen per unit volume than the first insulating film.

2. The semiconductor device according to claim 1, wherein the first insulating film is formed by a sputtering film-deposition method using one of argon gas, nitrogen gas, and mixed gas of (the) argon gas and (the) nitrogen gas.

3. The semiconductor device according to claim 1, wherein the first insulating film is formed of one of silicon nitride film and aluminum nitride film.

4. The semiconductor device according to claim 1, wherein the first insulating film is formed of insulating film having compressive stress.

5. The semiconductor device according to claim 1, wherein the second insulating film is formed of one of silicon oxide film, silicon nitride film, silicon oxynitride film, and multilayer film of silicon oxide film and silicon nitride film.

6. The semiconductor device according to claim 1 further comprising a third insulating film disposed between the first insulating film and the semiconductor layer, the third insulating film containing a small amount of hydrogen,
wherein a part of the third insulating film is opened for providing the third insulating film with an opening, and the schottky electrode that forms the schottky junction with the semiconductor layer is disposed to cover the opening.

7. The semiconductor device according to claim 6, wherein the third insulating film is formed by a sputtering film-deposition method using one of argon gas, nitrogen gas, and mixed gas of the argon gas and the nitrogen gas.

8. The semiconductor device according to claim 6, wherein the third insulating film is formed by a plasma-CVD (chemical vapor deposition) method, and then provided with an annealing treatment for reducing the amount of hydrogen contained.

9. The semiconductor device according to claim 6, wherein the third insulating film is formed of one of silicon nitride film and aluminum nitride.

10. A method for manufacturing a semiconductor device, the method comprising the steps of:
forming a semiconductor layer made of semiconductor;
forming an ohmic electrode on the semiconductor layer;
forming a schottky electrode on the semiconductor layer;
forming a first insulating film by a sputtering film-deposition method on the semiconductor layer at a place defined between the ohmic electrode and the schottky electrode for covering the place, the first insulating film also covering the schottky electrode that forms a schottky junction with the semiconductor layer; and
forming a second insulating film on the first insulating film, the second insulating film containing a greater amount of hydrogen per unit volume than the first insulating film.

11. The semiconductor device according to claim 1, wherein
the ohmic electrode forms a drain electrode and a source electrode, and
the schottky electrode forms a gate electrode disposed between the drain electrode and the source electrode.

12. The semiconductor device according to claim 1, wherein
the schottky electrode forms an anode electrode, and
the ohmic electrode forms a cathode electrode.
